(19) United States
(12) Patent Application Publication
(10) Pub. No.: US 2010/0084721 A1
(43) Pub. Date: Apr. 8, 2010

(54) Micro-Electromechanical System Microstructure

(76) Inventors: Mingching Wu, Hsinchu Hsien (TW); Ming-Hsi Tseng, Hsinchu Hsien (TW)

Correspondence Address: WHYTE HIRSCHBOECK DUDEK S C;INTELLECTUAL PROPERTY DEPARTMENT, 555 EAST WELLS STREET, SUITE 1900, MILWAUKEE, WI, 53202, US

(21) Appl. No.: 12/244,228

(22) Filed: Oct. 2, 2008

(51) Int. Cl. H01L 29/84

(52) U.S. Cl. 257/415; 257/E29.324

(57) ABSTRACT

A micro-electromechanical system microstructure includes: a substrate adapted to support an electrode thereon; a suspension mechanism supported on the substrate; and a movable active part adapted to cooperate with the electrode to define a capacitor therebetween, and suspended on the substrate through the suspension mechanism so as to be movable to and fro relative to the substrate and the electrode. The suspension mechanism includes at least one supporting frame that protrudes from and that cooperates with an outer surface of the substrate to define a frame space therebetween, and at least one cantilever beam interconnecting the supporting frame and the active part.

### BACKGROUND OF THE INVENTION

1. Field of the Invention

The invention relates to a micro-electromechanical system (MEMS) microstructure, more particularly to a MEMS microstructure including an active part suspended on a substrate through supporting frames and cantilever beams.

2. Description of the Related Art

Micro-electromechanical system (MEMS) devices, such as electrostatic accelerometers, sensors, actuators, and condenser microphones, normally include a substrate, an electrode supported on the substrate, and a conductive active part or mass that is suspended on the substrate and that is held to maintain flatness through springs or cantilever beams interconnecting the active part and the substrate. The active part is spaced apart from the electrode by a variable gap so as to cooperate with the latter to form a capacitor therebetween. When the active part undergoes vibration, such as due to an acoustic sound wave, to move to and fro relative to the electrode, the variable gap changes, thereby resulting in change in a capacitance between the active part and the electrode. However, since the active part and the springs or the cantilever beams are formed through film deposition techniques, internal residual stresses, such as compressive stress or tensile stress, are generated therein and are normally relatively high. As a consequence, the sensitivity of the active part tends to be decreased due to the tensile stress which hinders movement of the active part, or the active part and the cantilever beams are likely to deform due to the compressive stress, which results in undesired deviation of the designed value of the variable gap and In a decrease in a pull-in voltage. The pull-in effect occurs at the pull-in voltage. When the applied voltage reaches the pull-in voltage, the active part is undesirably pulled toward and is attached to the electrode, thereby resulting in short circuit of the MEMS device.

U.S. Pat. No. 6,535,460 discloses an acoustic transducer that includes a substrate, a backplate supported on the substrate and provided with an electrode thereon, and a diaphragm suspended on the substrate through springs which are connected to the substrate. Each of the springs is meandering so as to provide a stress relief function to relieve internal residual stresses present in the springs and the active part.

U.S. Pat. No. 6,168,906 discloses a corrugated micromachined diaphragm of a MEMS device that has flexible corrugated regions and stiff corrugated regions such that the stiff corrugated regions can maintain flatness of capacitor sense areas, and the flexible corrugated regions can provide high flexibility of spring areas. With the corrugated structure, the internal residual stresses present in the diaphragm can be relieved.

However, by virtue of the film deposition techniques, the springs and the active part normally have a film thickness of about 1 to 2 μm (note that the springs and the active part are normally formed by patterning a deposited film formed on the substrate), which is relatively thin and which has a relatively low stiffness, which, in turn, results in a relatively low pull-in voltage for the MEMS device. Moreover, when the residual stress in the active part is a type of compressive stress, the springs or the spring areas can provide only little effect in preventing deformation of the active part from occurring.

FIG. 1 illustrates a conventional MEMS microstructure of a MEMS device. The conventional MEMS microstructure includes a substrate 90, and an active part 91 suspended on the substrate 90 through cantilever beams 92 and cooperating with an electrode (not shown) to form a capacitor therebetween. Neither the active part 91 nor the cantilever beams 92 has stress-relieving design. As a consequence, the active part 91 and the cantilever beams 92 are likely to deform due to internal residual stress. Moreover, since the cantilever beams 92 are formed through film deposition techniques and thus have a relatively thin film thickness and a low stiffness, the active part 91 tends to be pulled and attached undesirably to the electrode.

### SUMMARY OF THE INVENTION

Therefore, an object of the present invention is to provide a micro-electromechanical system microstructure that can overcome at least one of the aforesaid drawbacks associated with the prior art.

According to the present invention, there is provided a micro-electromechanical system microstructure that comprises: a substrate adapted to support an electrode thereon; a suspension mechanism supported on the substrate; and a movable active part adapted to cooperate with the electrode to define a capacitor therebetween, and suspended on the substrate through the suspension mechanism so as to be movable to and fro relative to the substrate and the electrode. The suspension mechanism includes at least one supporting frame that protrudes from and that cooperates with an outer surface of the substrate to define a frame space therebetween, and at least one cantilever beam interconnecting the supporting frame and the active part.

### BRIEF DESCRIPTION OF THE DRAWINGS

Other features and advantages of the present invention will become apparent in the following detailed description of the preferred embodiment with reference to the accompanying drawings, of which:

FIG. 1 is a fragmentary schematic view of a conventional MEMS microstructure of a MEMS device;

FIG. 2 is a fragmentary partly sectional view of the preferred embodiment of a MEMS device according to this invention;

FIG. 3 is a fragmentary schematic view of a MEMS microstructure of the preferred embodiment;

FIG. 4 is a fragmentary perspective view of the MEMS microstructure of the preferred embodiment;

FIG. 5 is a schematic view to illustrate how a vertical wall of a supporting frame of the MEMS microstructure of the preferred embodiment responds to a compressive stress present in an active part of the MEMS microstructure;

FIG. 6 is a schematic view to illustrate how the vertical wall of the supporting frame of the MEMS microstructure of the preferred embodiment responds to a tensile stress present in the active part of the MEMS microstructure;

FIG. 7 is a plot of a two point profile for a cantilever beam of the microstructure of the preferred embodiment; and

FIG. 8 is a plot of a two point profile for a cantilever beam of a microstructure of the conventional MEMS microstructure of FIG. 1.

### DETAILED DESCRIPTION OF THE PREFERRED EMBODIMENT

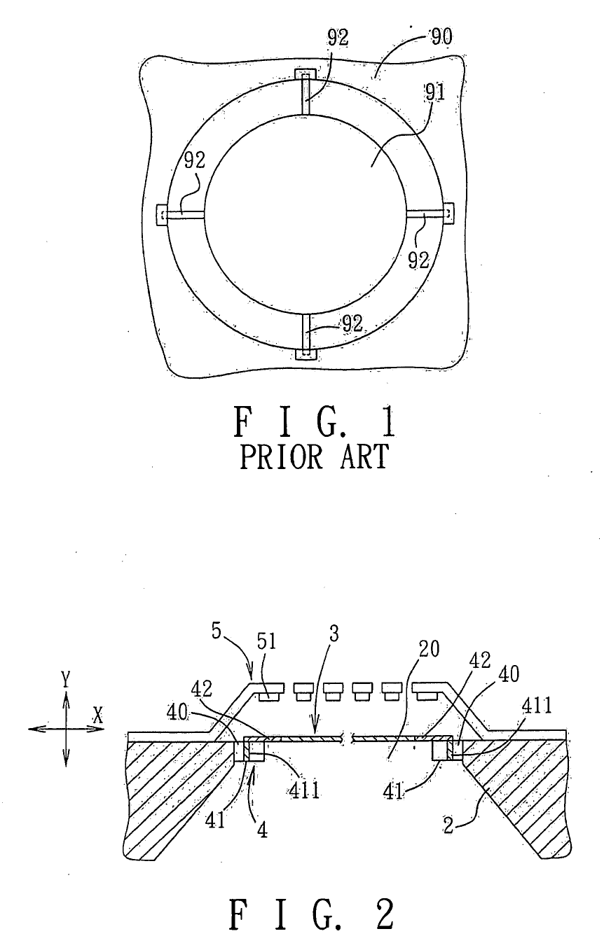

FIGS. 2 to 4 illustrate the preferred embodiment of a micro-electromechanical system (MEMS) device, such as electrostatic accelerometers, sensors, actuators, and condenser microₚhones, according to the present invention. In this embodiment, the MEMS device is a condenser microphone. The MEMS device includes a MEMS microstructure and a backplate 5 provided with an electrode 51 thereon. The MEMS microstructure includes: a substrate 2 of polysilicon formed with a central hole 20, the backplate 5 together with the electrode 51 being supported on a periphery of the central hole 20 in the substrate 2; a suspension mechanism 4 supported on the substrate 2; and a movable active part 3 cooperating with the electrode 51 to define a capacitor therebetween, aligned with the central hole 20 in a vertical direction (Y), and suspended on the substrate 2 through the suspension mechanism 4 so as to be movable to and fro relative to the substrate 2 and the electrode 51 in the vertical direction (Y). The suspension mechanism 4 includes a plurality of supporting frames 41, each of which protrudes from and cooperates with an outer surface of the substrate 2 to define a frame space 40 therebetween, and a plurality of cantilever beams 42, each of which interconnects the active part 3 and a respective one of the supporting frames 41.

In this embodiment, the active part 3 is a diaphragm of a thin film, and is movable to and fro relative to the substrate 2 in the vertical direction (Y) normal to the diaphragm when the active part 3 is actuated. Each of the supporting frames 41 has a plate-like vertical wall 411 that is separate from the outer surface of the substrate 2, that confines one side of the frame space 40, and that is deformable toward the outer surface of the substrate 2 in a horizontal direction (X) perpendicular to the vertical direction (Y). Preferably, the vertical wall 411 of each of the supporting frames 41 is arcuate in shape, and is convex toward the outer surface of the substrate 2 so as to facilitate deformation of the vertical wall 411 toward the outer surface of the substrate 2 and so as to prevent deformation of the vertical wall 411 away from the outer surface of the substrate 2. As such, internal residual stresses, such as the compressive stress and the tensile stress, in the active part 3 and the cantilever beams 42 can be relieved through the supporting frames 41.

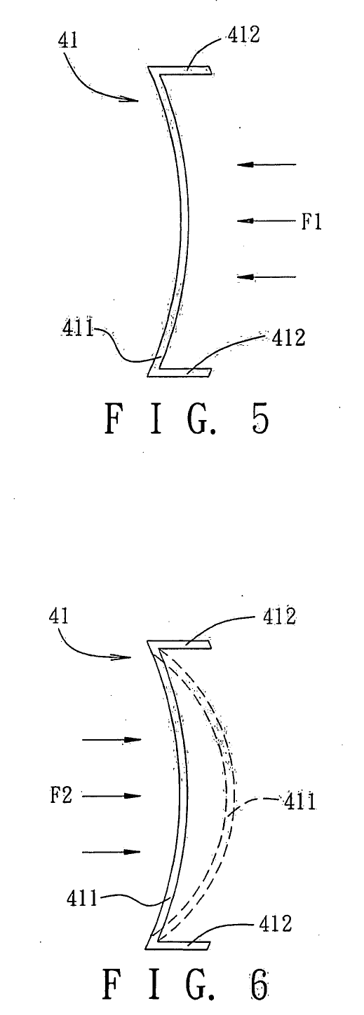

FIG. 5, in combination with FIG. 4, illustrates how the convex shape of the vertical wall 411 of each of the supporting frames 41 is advantageous in preventing the vertical wall 411 from being deformed toward the active part 3 when the residual stress present in the active part 3 is a type of compressive stress so as to provide a stress relief function for the active part 3 and to eliminate or at least alleviate the extent of deformation of the active part 3. In FIG. 5, the compressive stress in the active part 3 generates a pulling force (F₁) that pulls the vertical walls 411 of the supporting frames 41 through the cantilever beams toward the active part 3, which can result in deformation of the cantilever beams 42 and the active part 3 if the vertical walls 411 of the supporting frames 41 are deformed toward the active part 3 by the pulling force (F₁). Hence, it is critical for the vertical walls 411 to have a structural strength that can prevent or at least alleviate the extent of deformation thereof. By virtue of the convex shape toward the outer surface of the substrate 2, the structural strength of each of the vertical walls 411 in preventing deformation thereof toward the active part 3 is considerably enhanced, which can prevent deformation of the active part 3 and the cantilever beams 42 and maintain flatness of the active part 3.

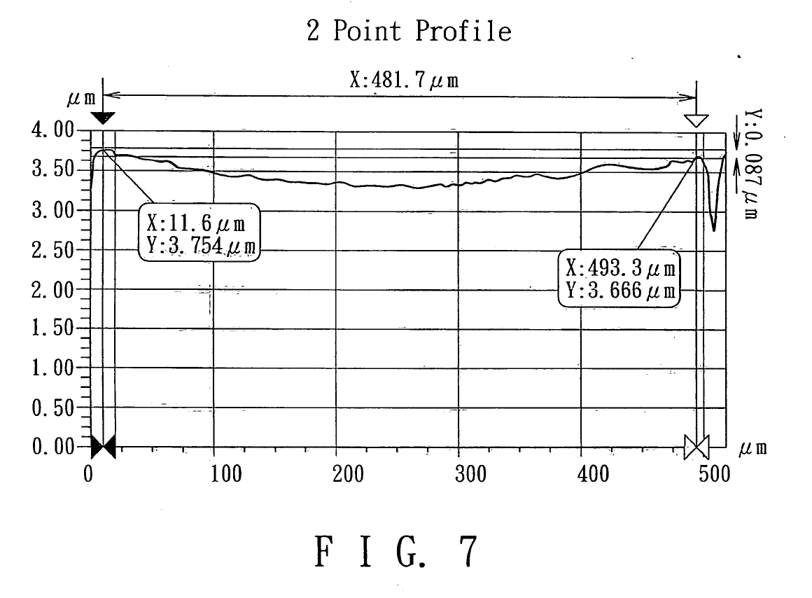

FIG. 6, in combination with FIG. 4, illustrates how the convex shape of the vertical wall 411 of each of the supporting frames 41 is advantageous in facilitating deformation of the vertical wall 911 toward the outer surface of the substrate 2 when the residual stress present in the active part 3 is a type of tensile stress so as to provide a stress relief function for the active part 3 and to eliminate excessive tightness of the active part 3, which can hinder movement of the active part 3 relative to the electrode 51 and can result in a decrease in the sensitivity of the active part 3. In FIG. 6, the tensile stress in the active part 3 generates a pushing force (F₂) that pushes the vertical wall 411 toward the outer surface of the substrate 2. By virtue of the convex shape toward the outer surface of the substrate 2, the vertical wall 411 of each of the supporting frames 91 can be easily deformed toward the outer surface of the substrate 2 by the pushing force (F₂), thereby permitting relief of the tensile stress in the active part 3 and eliminating or at least alleviating the excessive tightness of the active part 3 resulting from the pushing force (F₂).

In this embodiment, each of the cantilever beams 42 is in the form of a thin film, and has a film thickness (h₁) in the vertical direction (Y). The vertical wall 411 of each of the supporting frames 41 has a height (h₂) in the vertical direction (Y) that is greater than the film thickness (h₁) of each of the cantilever beams 42. Each of the supporting frames 41 further has two opposite plate-like side walls 412 extending respectively from two opposite ends of the vertical wall 411 to the outer surface of the substrate 2 and cooperating with the vertical wall 411 and the outer surface of the substrate 2 to define the frame space 40 thereamong. Each of the side walls 412 has a height (h₃) in the vertical direction (Y) that is greater than the film thickness (h₁) of each of the cantilever beams 42. As such, with the inclusion of the supporting frames 41 in the suspension mechanism 4, the stiffness of the suspension mechanism 4 in the vertical direction (Y) is considerably increased, and thus is higher than that of the prior art (which includes only the cantilever beams), i.e., the suspension mechanism 4 of this invention is more difficult to be pulled in the vertical direction (Y) by the electrode 51 than that of the prior art, thereby increasing the pull-in voltage of the MEMS device as compared to the conventional MEMS device.

In this embodiment, each of the cantilever beams 42 is connected to the vertical wall 411 of the respective one of the supporting frames 41 at a middle position between the two opposite ends of the vertical wall 411.

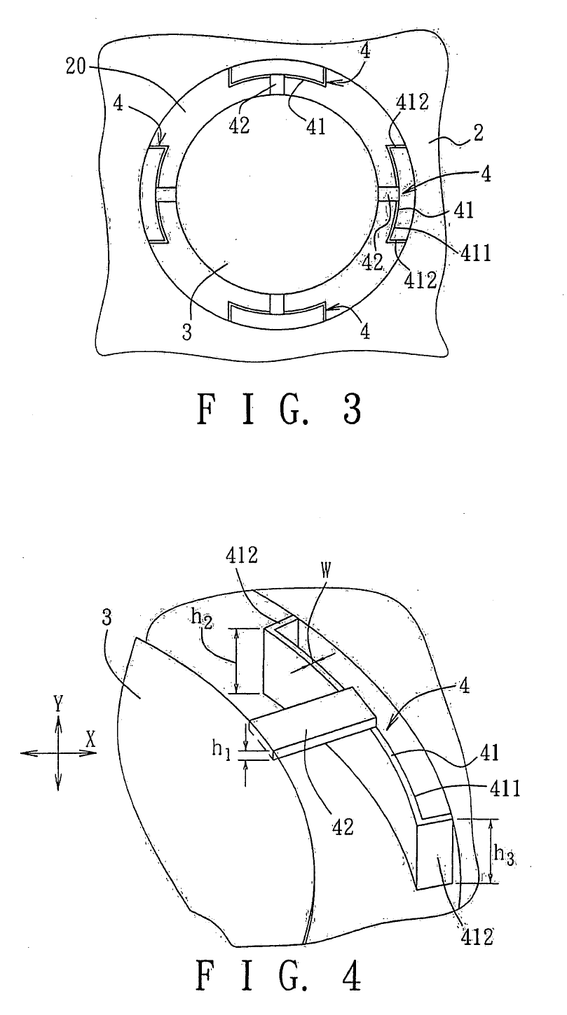

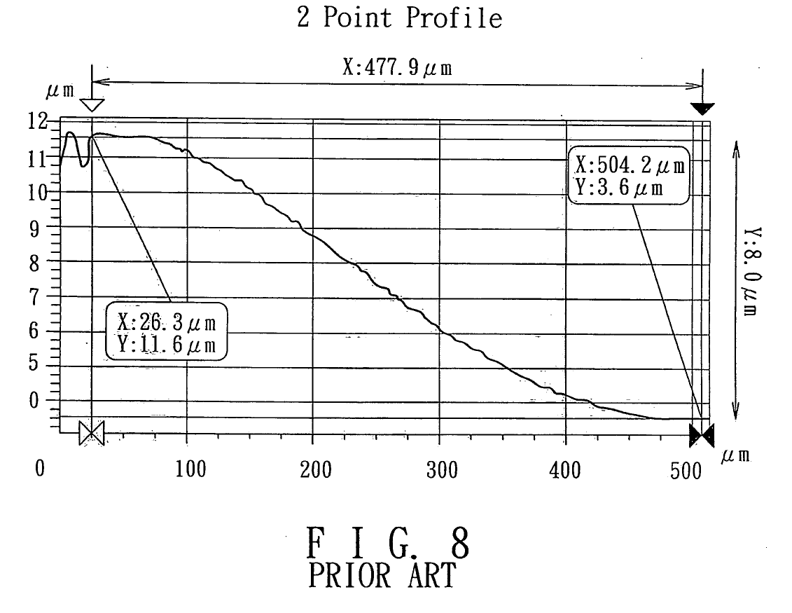

FIG. 7 is a plot of a two point profile for a cantilever beam 42 of the microstructure of the preferred embodiment (see FIG. 3) that was tested and that was measured using an optical interference measuring apparatus (not shown). The deformation profile of the cantilever beam 412 was obtained by measuring x-y coordinates of two points of the cantilever beam 412. The deformation of the tested cantilever beam 412 of the MEMS microstructure was about 0.09 μm. FIG. 8 is a plot of a two point profile for a cantilever beam of a microstructure of the conventional MEMS microstructure of FIG. 1 that was tested and that was measured using the aforesaid apparatus. The active part and the cantilever beams of the tested conventional MEMS microstructure have sizes and shapes that are substantially the same as those of the tested MEMS microstructure of this invention. The deformation of the tested cantilever beam of the conventional MEMS microstructure was about 8 μm. Note that measured residual stresses in the substrate 2 of the tested MEMS microstructure of this invention and the substrate of the conventional MEMS microstructure were about 50 MPa. Compared to the conventional MEMS microstructure, the MEMS microstructure of this invention exhibits a relatively high stress relieving ability.

Simulations for calculating de format ions and pull-in voltages of the MEMS microstructure of this invention and the conventional MEMS microstructure of FIG. 1 were conducted using COVENTOR WAVE SIMULATOR (developed by MEMS CAP company). Parameters used for simulation number 1 (S1: Example 1) for the MEMS microstructure of this invention include: the active part 3 with a diameter of 670 μm and a film thickness of 1 μm; four supporting frames 41 with a film thickness (indicated as (w) in FIG. 4) of 2 μm and a height (h₂) of 6 μm; a total length of 100 μm of each of the supporting frames 41 and a respective one of the cantilever beams 42; and a compressive stress of 20 MPa. Parameters used for simulation number 2 (S2: Example 2) for the MEMS microstructure of this invention differ from S1 in that there are eight supporting frames 41 formed in the MEMS microstructure of S2. Parameters used for simulation number 3 (S3: Comparative Example 1) for the conventional MEMS microstructure of FIG. 1 include: the active part with a diameter of 670 μm and a film thickness of 1 μm; four cantilever beams with a length of 100 μm, a width of 28 μm and a film thickness of 1 μm; and a compressive stress of 20 MPa. The simulation results are shown in Table 1.

| | Deformation, | Pull-in |
|---|---|---|
| Simulation | μm | voltage, V |
| Example 1 (S1) | 0.02 | 19.75 |
| Example 2 (S2) | 0.034 | 29.25 |
| Comparative | 2.4 | 8.5 |
| Example 1 (S3) | | |

The simulation results show that the active part 3 of the MEMS microstructure of this invention has a much lower deformation and a much higher pull-in voltage than those of the conventional MEMS microstructure.

With the inclusion of the supporting frames 41 in the suspension mechanism 4 of the MEMS microstructure of the MEMS device of this invention, the aforesaid drawbacks associated with the prior art can be eliminated.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A micro-electromechanical system microstructure comprising:
a substrate adapted to support an electrode thereon;
a suspension mechanism supported on said substrate; and
a movable active part adapted to cooperate with the electrode to define a capacitor therebetween, and suspended on said substrate through said suspension mechanism so as to be movable to and fro relative to said substrate and the electrode;
wherein said suspension mechanism includes at least one supporting frame that protrudes from and that cooperates with an outer surface of said substrate to define a frame space therebetween, and at least one cantilever beam interconnecting said supporting frame and said active part.

2. The micro-electromechanical system microstructure of claim 1, wherein said active part is movable to and fro relative to said substrate in a vertical direction, said cantilever beam being in the form of a thin film and having a film thickness in the vertical direction, said supporting frame having a plate-like vertical wall that is separate from said outer surface of said substrate, and that confines one side of said frame space, said vertical wall having a height in the vertical direction that is greater than the film thickness of said cantilever beam.

3. The micro-electromechanical system microstructure of claim 2, wherein said supporting frame further has two opposite plate-like side walls extending respectively from two opposite ends of said vertical wall to said outer surface of said substrate and cooperating with said vertical wall and said outer surface of said substrate to define said frame space thereamong, each of said side walls having a height in the vertical direction that is greater than the film thickness of said cantilever beam.

4. The micro-electromechanical system microstructure of claim 3, wherein said vertical wall is arcuate in shape and that is convex toward said outer surface of said substrate.

5. The micro-electromechanical system microstructure of claim 4, wherein said cantilever beam is connected to said vertical wall at a middle position between said two opposite ends of said vertical wall.

6. The micro-electromechanical system microstructure of claim 1, wherein said active part is movable to and fro relative to said substrate in &vertical direction, said supporting frame having a plate-like vertical wall that is separate from said outer surface of said substrate, that confines one side of said frame space, and that is deformable toward said outer surface of said substrate.

7. The micro-electromechanical system microstructure of claim 6, wherein said vertical wall is arcuate in shape, and is convex toward said outer surface of said substrate.

8. A micro-electromechanical system device comprising:
an electrode; and
a MEMS microstructure including
a substrate supporting said electrode thereon,
a suspension mechanism supported on said substrate, and
a movable active part cooperating with said electrode to define a capacitor therebetween, and suspended on said substrate through said suspension mechanism so as to be movable to and fro relative to said substrate and said electrode;
wherein said suspension mechanism includes a plurality of supporting frames, each of which protrudes from and cooperates with an outer surface of said substrate to define a frame space therebetween, and a plurality of cantilever beams, each of which interconnects a respective one of said supporting frames and said active part.

9. The micro-electromechanical system device of claim 8, wherein said active part is movable to and fro relative to said substrate in a vertical direction, each of said supporting frames having a plate-like vertical wall that is separate from said outer surface of said substrate, that confines one side of said frame space, and that is deformable toward said outer surface of said substrate.

10. The micro-electromechanical system device of claim 9, wherein said vertical wall of each of said supporting frames is arcuate in shape, and is convex toward said outer surface of said substrate.

11. The micro-electromechanical system device of claim 9, wherein each of said cantilever beams is in the form of a thin film and has a film thickness in the vertical direction, said vertical wall of each of said supporting frames having a height in the vertical direction that is greater than the film thickness of each of said cantilever beams.
